(19) United States
(12) Patent Application Publication
(10) Pub. No.: US 2026/0190368 A1
(43) Pub. Date: Jul. 2, 2026

(54) SEMICONDUCTOR STRUCTURE STACKED TRANSISTORS

(71) Applicant: TAIWAN SEMICONDUCTOR MANUFACTURING COMPANY, LTD., Hsinchu (TW)

(72) Inventors: Zheng Hui LIM, Hsinchu City (TW); Ji-Yin TSAI, Hsinchu County (TW)

(73) Assignee: TAIWAN SEMICONDUCTOR MANUFACTURING COMPANY, LTD., Hsinchu (TW)

(21) Appl. No.: 19/006,598

(22) Filed: Dec. 31, 2024

(51) Int. Cl. H10D 30/01; H10D 30/00; H10D 30/67; H10D 62/10; H10D 62/80; H10D 64/23; H10D 84/03; H10D 84/85

(52) U.S. Cl. CPC H10D 30/0191; H10D 30/017; H10D 30/502; H10D 30/6735; H10D 30/6757; H10D 62/115; H10D 62/121; H10D 62/882; H10D 64/251; H10D 84/038; H10D 84/851

(57) ABSTRACT

A method includes following steps. A first semiconductor nanostructure is formed, and a second semiconductor nanostructure is formed above the first semiconductor nanostructure. First and second gate dielectric layers are respectively formed on the first and second semiconductor nanostructures. A dipole dopant source layer is deposited over the first gate dielectric layer and the second gate dielectric layer. A dummy fill material is formed without performing a CMP process on the dummy fill material. The dipole dopant source layer is etched by using the dummy fill material as an etch mask. After etching the dipole dopant source layer, a dipole dopant of the dipole dopant source layer is incorporated into the first gate dielectric layer.

### BACKGROUND

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (CFET) where an n-type multi-gate transistor and a p-type multi-gate transistor are stacked vertically, one over the other. While existing CFET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a complementary field-effect transistor (CFET) schematic in a three-dimensional view, in accordance with some embodiments.

FIGS. 2A, 2B, 3A, 3B and 4 are three-dimensional views at various stages of CFET fabrication, in accordance with some embodiments.

FIGS. 5, 6, 7, 8A, and 8C illustrate cross-sectional views at various stages of CFET fabrication along a similar cross-section as reference cross-section A-A′ in FIG. 1, in accordance with some embodiments.

FIG. 8B illustrate cross-sectional views at various stages of CFET fabrication along a similar cross-section as reference cross-section B-B′ in FIG. 1, in accordance with some embodiments.

FIGS. 9-10B are cross-sectional views of a CFET device at various stages of manufacturing, in accordance with some other embodiments of the present disclosure.

FIGS. 11-12B are cross-sectional views of a CFET device at various stages of manufacturing, in accordance with some other embodiments of the present disclosure.

FIGS. 13A-13B are cross-sectional views of a CFET device in accordance with some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced with the down-scaling of the integrated circuits. Throughout the description, the terms “FET” and “transistor” are used interchangeably.

According to various embodiments, CFETs are formed. A CFET includes a lower nanostructure-FET and an upper nanostructure-FET. An isolation nanostructure (also referred to as a nanostructure isolation material) is formed between the nanostructures of the lower nanostructure-FET and the nanostructures of the upper nanostructure-FET. This isolation nanostructure can be achieved by replacing a germanium-rich silicon germanium (SiGe) layer with a dielectric layer. The CFET fabrication process involves the epitaxial growth of the germanium-rich SiGe layer on a lower silicon (Si) layer, followed by the growth of an upper Si layer on the germanium-rich SiGe layer. However, this approach is susceptible to the diffusion of germanium atoms from the germanium-rich SiGe layer into the adjacent silicon layer, which can degrade the electronic properties of the device. Moreover, the CFET architecture's reliance on an increased number of nanostructures to boost performance results in a cumulative thickness of SiGe layers that may exceed a threshold. This excessive thickness is particularly problematic in the germanium-rich SiGe layer, where it can lead to a significant number of dislocations. These dislocations can adversely affect the quality of the epitaxial layers, such as the upper silicon layer, grown on the germanium-rich SiGe layer, potentially compromising the device's structural and electronic integrity.

To mitigate these challenges, the present disclosure, in various embodiments, provides an improved CFET fabrication process that incorporates a two-dimensional (2D) material layer between the SiGe layer and the silicon layer, particularly on the top surface of the germanium-rich SiGe layer. This 2D material layer is multifunctional, serving as a germanium diffusion barrier that impedes the migration of Ge atoms from the SiGe layer into the silicon layer, thereby preserving the silicon layer's purity and performance. Additionally, the 2D material layer further serves to prevent dislocations within the SiGe layer from propagating to the silicon layer grown above it. For example, a graphene layer can be formed on the germanium-rich SiGe layer to serve as a germanium diffusion barrier and a dislocation barrier.

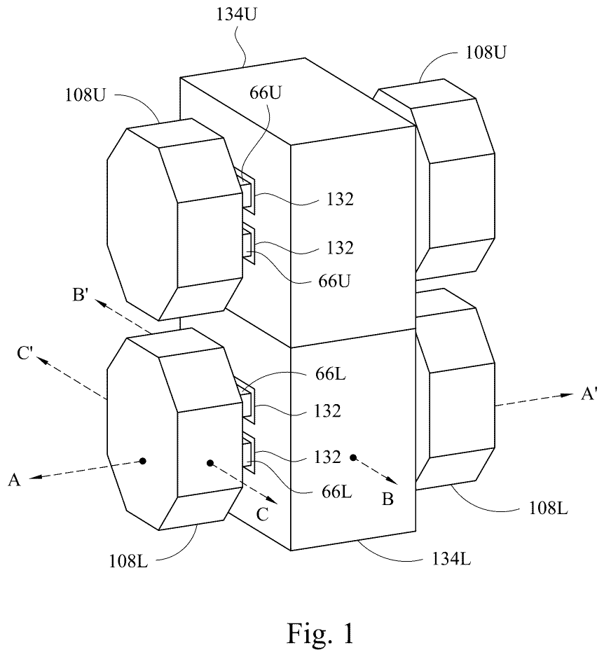

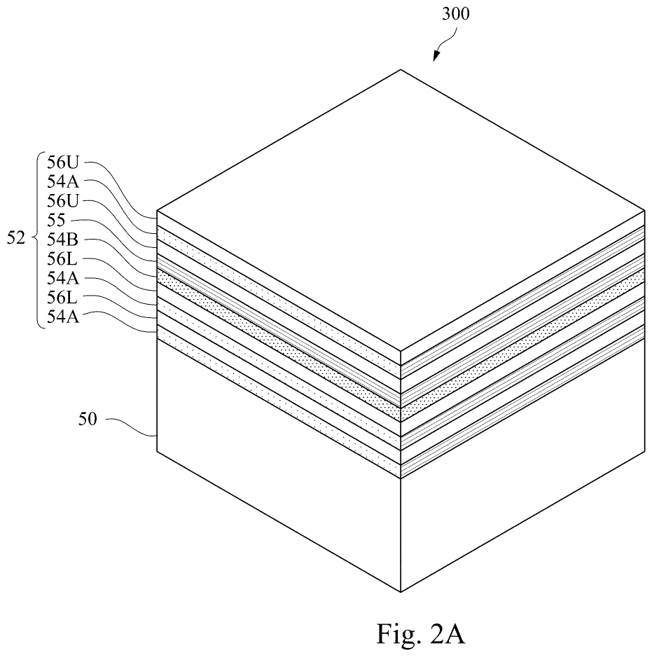

FIG. 1 illustrates an example of a CFET schematic, in accordance with some embodiments. FIG. 1 is a three-dimensional view, where some features of the CFETs are omitted for illustration clarity. While Gate-All-Around (GAA) transistors (such as nanostructure-FETs) are illustrated, the concept of the present disclosure can also be applied to the formation of other types of transistors such as planar transistors, Fin Field-Effect Transistors (FinFETs), or the like. Furthermore, in the illustrated examples, the upper FETs are PFETs, and lower FETs are NFETs, while in other embodiments, upper FETs may also be NFETs, and the lower FETs may be PFET.

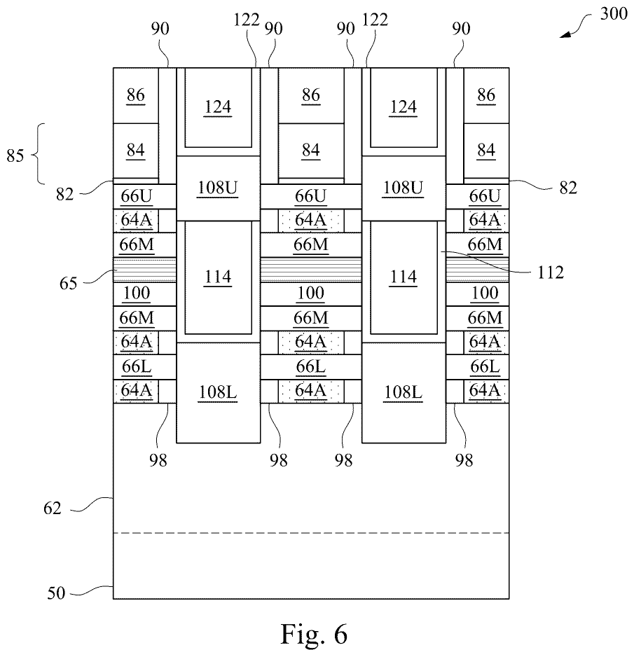

The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Each of the nanostructure-FETs include semiconductor nanostructures 66 (including lower semiconductor nanostructures 66L and upper semiconductor nanostructures 66U), where the semiconductor nanostructures 66 act as active regions or channel regions (also referred to as channel layers, semiconductor channels regions, or semiconductor channel layers) for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A nanostructure isolation material (not explicitly illustrated in FIG. 1, see 100 in FIG. 6) may be used to separate and electrically isolate the upper semiconductor nanostructures 66U from the lower semiconductor nanostructures 66L.

Gate dielectrics 132 are along top surfaces, sidewalls, and bottom surfaces of the semiconductor nanostructures 66. Gate electrodes 134 (including a lower gate electrode 134L and an upper gate electrode 134U) are over the gate dielectrics 132 and around the semiconductor nanostructures 66. Source/drain regions 108 (including lower epitaxial source/drain regions 108L and upper epitaxial source/drain regions 108U) are disposed at opposing sides of the gate dielectrics 132 and the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, a lower gate electrode 134L may optionally be separated from an upper gate electrode 134U by an isolation layer. Alternatively, a lower gate electrode 134L may be coupled to an upper gate electrode 134U. Further, the upper epitaxial source/drain regions 108U may be separated from lower epitaxial source/drain regions 108L by one or more dielectric layers. The isolation features between channel regions, gates, and source/drain regions allow for vertically stacked transistors, thereby improving device density. Because of the vertically stacked nature of CFETs, the schematic may also be referred to as stacking transistors or folding transistors.

FIG. 1 further illustrates reference cross-sections that are used in later figures. Cross-section A-A′ is parallel to a longitudinal axis of the semiconductor nanostructures 66 of a CFET and in a direction of, for example, a current flow between the source/drain regions 108 of the CFET. Cross-section B-B′ is perpendicular to cross-section A-A′ and along a longitudinal axis of a gate electrode 134 of a CFET. Cross-section C-C′ is parallel to cross-section B-B′ and extends through the source/drain regions 108 of the CFETs. Subsequent figures refer to these reference cross-sections for clarity.

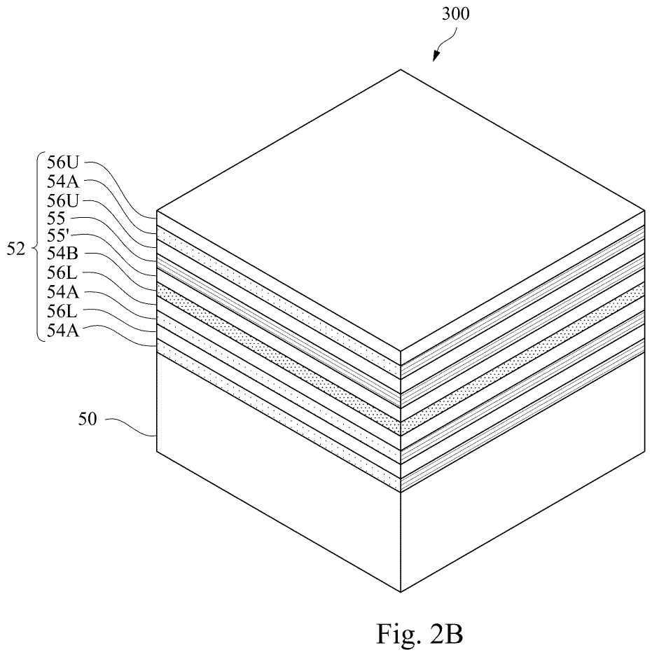

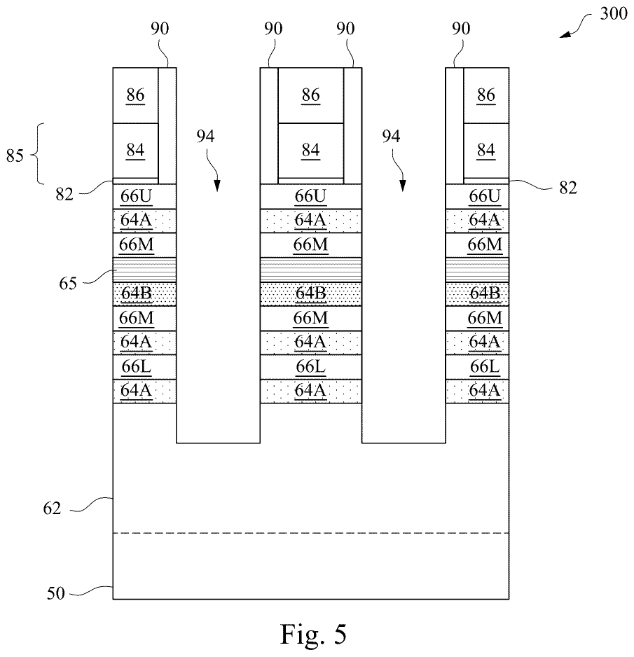

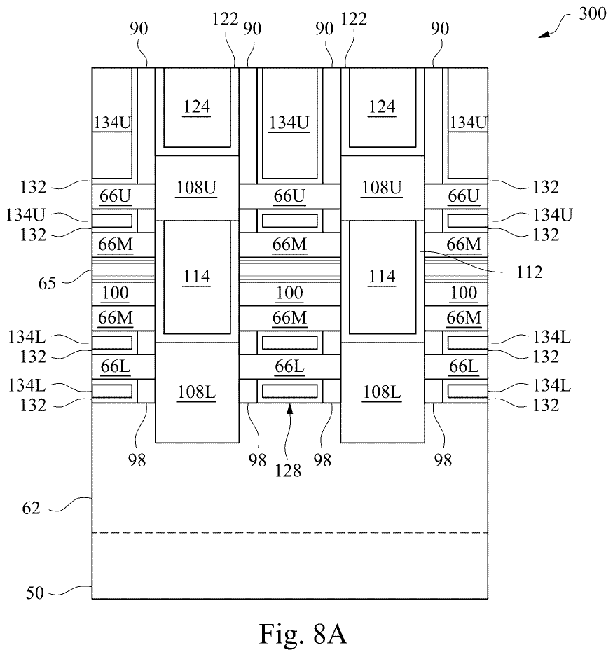

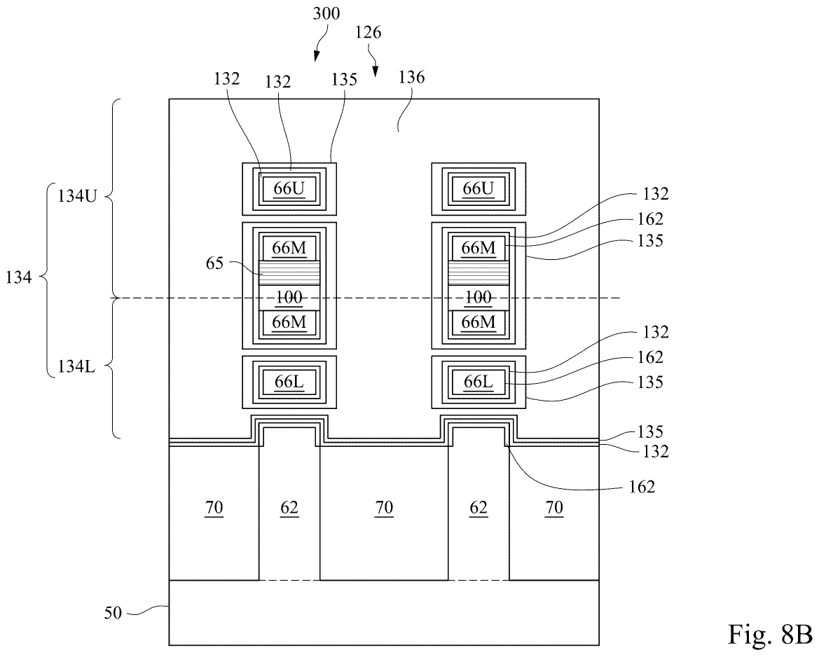

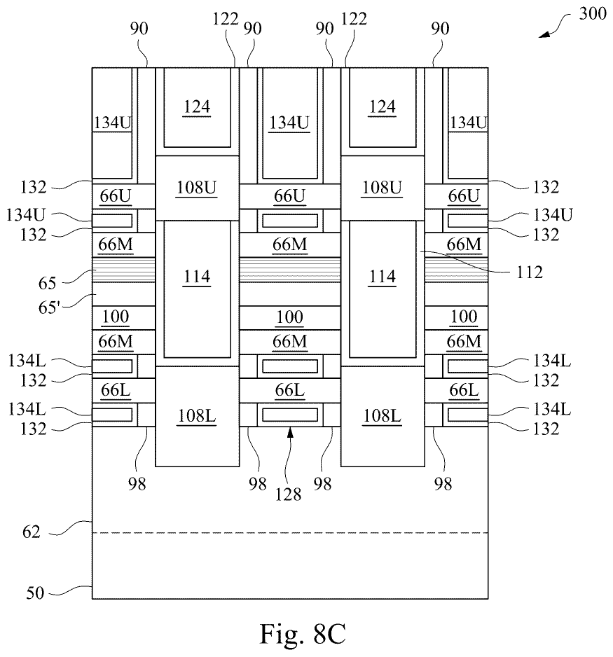

FIGS. 2A-8C include three-dimensional views and cross-sectional views of a CFET device 300 at various stages of manufacturing, in accordance with some embodiments of the present disclosure. FIGS. 2A, 2B 3A, 3B and 4 are three-dimensional views showing a similar three-dimensional view as FIG. 1. FIGS. 5, 6, 7, 8A, and 8C illustrate cross-sectional views along a similar cross-section as reference cross-section A-A′ in FIG. 1. FIG. 8B illustrate cross-sectional views along a similar cross-section as reference cross-section B-B′ in FIG. 1.

In FIG. 2A, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 52 is formed over the substrate 50. The multi-layer stack 52 includes dummy layers 54 (including first dummy layers 54A and a second dummy layer 54B), semiconductor layers 56 (including one or more lower semiconductor layers 56L and one or more upper semiconductor layers 56U) alternating with the dummy layers, and a 2D material layer 55 interposing the second dummy layer 54B and an upper semiconductor layer 56U adjacent the second dummy layer 54B. The lower semiconductor layers 56L and a subset of the first dummy layers 54A are disposed below the second dummy layer 54B. The upper semiconductor layers 56U and another subset of the first dummy layers 54A are disposed above the second dummy layer 54B. As subsequently described in greater detail, the dummy layers 54 will be removed and the semiconductor layers 56 will be patterned to form channel regions of CFETs. Specifically, a lower semiconductor layer 56L will be patterned to form a channel region of the lower nanostructure-FET of the CFET, and an upper semiconductor layer 56U will be patterned to form a channel region of the upper nanostructure-FET of the CFET.

The multi-layer stack 52 is illustrated as including four of the dummy layers 54, four of the semiconductor layers 56, and a 2D material layer 55. It is appreciated that the multi-layer stack 52 may include any number of the dummy layers 54 and the semiconductor layers 56, and more than one 2D material layer 55. Each layer of the dummy layers 54 and the semiconductor layers 56 may be epitaxially grown by a process such as vapor phase epitaxy (VPE) or molecular beam epitaxy (MBE), deposited by a process such as chemical vapor deposition (CVD) or atomic layer deposition (ALD), or the like.

The first dummy layers 54A are formed of a first semiconductor material, and the second dummy layer 54B is formed of a second semiconductor material. The first and second semiconductor materials may be selected from the candidate semiconductor materials of the substrate 50. The semiconductor materials of the first dummy layers 54A and the second dummy layer 54B will be subsequently described in greater detail. The first and second semiconductor materials have a high etching selectivity to one another. As such, the material of the second dummy layer 54B may be removed at a faster rate than the material of the first dummy layers 54A in subsequent processing.

The semiconductor layers 56 (including the lower semiconductor layers 56L and upper semiconductor layers 56U) are formed of one or more semiconductor material(s). The semiconductor material(s) may be selected from the candidate semiconductor materials of the substrate 50. In some embodiments, the semiconductor layers 56 are formed of a group IV-V material or a group III-V material. The lower semiconductor layers 56L and the upper semiconductor layers 56U may be formed of the same semiconductor material, or may be formed of different semiconductor materials. In some embodiments, the lower semiconductor layers 56L and the upper semiconductor layers 56U are both be formed of a semiconductor material suitable for p-type devices and n-type devices, such as silicon. In some embodiments, the lower semiconductor layers 56L are formed of a semiconductor material suitable for p-type devices, such as germanium or silicon-germanium, and the upper semiconductor layers 56U are formed of a semiconductor material suitable for n-type devices, such as silicon or carbon-doped silicon. The semiconductor material(s) of the semiconductor layers 56 will be subsequently described in greater detail. The semiconductor material(s) of the semiconductor layers 56 have a high etching selectivity to the semiconductor materials of the dummy layers 54. As such, the materials of the dummy layers 54 may be removed at a faster rate than the material of the semiconductor layers 56 in subsequent processing.

Some layers of the multi-layer stack 52 may be thicker than other layers of the multi-layer stack 52. The thickness of the second dummy layer 54B may be different (e.g., greater or less) than the thickness of at least one of the first dummy layers 54A. In some embodiments, the second dummy layer 54B has a large thickness, such as a greater thickness than at least one of the first dummy layers 54A. Forming the second dummy layer 54B to a large thickness allows the second dummy layer 54B to be more easily removed in subsequently processing. In some embodiments, a thickness ratio of a second dummy layer 54B to a first dummy layer 54A is in a range from about 1.2 to about 3. Additionally, the thickness of at least one of the semiconductor layers 56 may be different (e.g., greater or less) than the thickness(es) of at least one of the first dummy layers 54A and/or the second dummy layer 54B. In some embodiments, at least one of the semiconductor layers 56 may be thicker than at least one of the dummy layers 54. In some embodiments, the lower semiconductor layers 56L have different thicknesses. For example, a bottommost one of the lower semiconductor layers 56L has a thickness greater than a thickness of a topmost one of the lower semiconductor layers 56L. In some embodiments, the upper semiconductor layers 56U have different thicknesses. For example, a topmost one of the upper semiconductor layers 56U has a thickness greater than a thickness of a bottommost one of the upper semiconductor layers 56U.

In some embodiments, the first dummy layers 54A are formed of silicon germanium with a first germanium atomic percentage, the second dummy layer 54B is a germanium-rich layer formed of silicon germanium with a second germanium atomic percentage that is higher than the first germanium atomic percentage. The difference between the second germanium atomic percentage and the first germanium atomic percentage may be higher than about 30 percent, and may be in the range between about 40 percent and about 70 percent. The higher germanium atomic percentage allows the second dummy layer 54B to be etched at a faster rate than the first dummy layers 54A, and allow the second dummy layer 54B to be completed removed during a subsequent etching process, as discussed hereinafter.

In some embodiments, the 2D material layer 55 is a graphene layer, which is a two-dimensional planar sheet of carbon atoms arranged in a hexagonal benzene-ring structure. Structurally, graphene has hybrid orbitals formed by sp² hybridization. In the sp² hybridization, the 2s orbital and two of the three 2p orbitals mix to form three sp² orbitals. The one remaining p-orbital forms a pi (π)-bond between the carbon atoms. Similar to the structure of benzene, the structure of graphene has a conjugated ring of the p-orbitals, i.e., the graphene structure is aromatic. Unlike other allotropes of carbon such as diamond, amorphous carbon, carbon nanofoam, or fullerenes, graphene is only one atomic layer thin. In some embodiments, the 2D material layer 55 is a monolayer of graphene or a plurality of monolayers of graphene. The total count of monolayer(s) of graphene depends on a desired thickness of the 2D material layer 55. In some embodiments, the 2D material layer 55 has a thickness in a range in a range from about 1 Å to 50 Å. In some embodiments, the 2D material layer 55 has a thickness less than a thickness of one of the dummy layers 54 and/or a thickness of the one of the semiconductor layers 56.

In some embodiments, the 2D material layer 55, such as graphene layer, can be formed on the dummy layer 54B (e.g., a germanium-rich SiGe layer) by using, for example, CVD, MBE, a transfer process, and/or other suitable approaches. For example, in some embodiments where the 2D material layer 55 is formed using CVD, the 2D material layer 55 can be deposited by using a carbon-containing precursor gas, such as methane (CH₄), at an elevated temperature to facilitate the decomposition of the carbon-containing precursor gas and the subsequent deposition of carbon atoms onto the surface of the dummy layer 54B. The growth parameters, including gas flow rates, CVD chamber pressure, and temperature, are controlled to achieve a uniform graphene coverage over the dummy layer 54B. The duration of the growth process is controlled to form a monolayer or few-layer graphene, depending on the desired thickness of the 2D material layer 55. In some embodiments, as illustrated in FIG. 2B, the 2D material layer 55 is grown on a catalyst layer 55′, such as a copper (Cu) layer, by using a carbon-containing precursor gas.

In some embodiments where the 2D material layer 55 is formed using MBE, the 2D material layer 55 can be deposited in a vacuum chamber in which a solid carbon source, such as graphite, is heated to sublimate carbon atoms, which are then deposited onto the surface of the dummy layer 54B to form a graphene layer.

In some embodiments where the 2D material layer 55 is formed using a transfer process, the 2D material layer 55 is initially synthesized on a crystalline substrate using a CVD process. The 2D material layer 55 is then coated with a polymer layer, such as polymethyl methacrylate (PMMA), and a thermal release tape. Then, the 2D material layer 55 is mechanically or chemically exfoliated from the crystalline substrate and then transferred onto the dummy layer 54B. Next, the thermal release tape can be removed by, for example, baking the thermal release tape, so that the thermal release tape loses adhesiveness. Next, the polymer layer can be removed by, for example, etching or dissolving. After removal of the polymer layer, the 2D material layer 55 remains on the dummy layer 54B, and is ready for the epitaxial growth of the upper semiconductor layer 56U.

After forming the 2D material layer 55 (e.g., graphene layer) over the second dummy layer 54B (e.g., germanium-rich SiGe layer), an upper semiconductor layer 56U (e.g., Si layer) is grown on the 2D material layer 55 by using, for example, Van der Waals epitaxy. This epitaxy method takes advantage of the weak van der Waals forces between the 2D material, such as graphene, and the semiconductor material, such as silicon, in the upper semiconductor layer 56U. The absence or minimal presence of dangling bonds in the 2D material allows for silicon growth without the constraints of lattice matching. To achieve Van der Waals epitaxy, the growth environment is controlled, such as within a molecular beam epitaxy (MBE) or chemical vapor deposition (CVD) chamber, where the conditions such as temperature, pressure, and precursor gas flow rates are tuned to promote the desired Si layer formation. During the growth process, the silicon atoms are deposited onto the graphene layer, where they are able to form a crystalline structure due to the weak Van der Waals interactions. These interactions allow the silicon atoms to align themselves in a manner that minimizes strain and defects.

The 2D material layer 55, positioned between the second dummy layer 54B and the upper semiconductor layer 56U, can act as a barrier to germanium diffusion, effectively preventing the migration of germanium atoms from the second dummy layer 54B into the upper semiconductor layer 56U. Additionally, the 2D material layer 55 can also act as a dislocation barrier, inhibiting the propagation of dislocations from the underlying second dummy layer 54B to the overlying upper semiconductor layer 56U. This may be attributed to the strong in-plane carbon-carbon bonds present in the 2D material layer 55, such as those in graphene, which provide significant resistance to shear forces. Dislocations, which include line defects in a crystal lattice, require a pathway to propagate. The robust in-plane strength of graphene obstructs these pathways, thereby preventing dislocations from traversing through the 2D material layer 55.

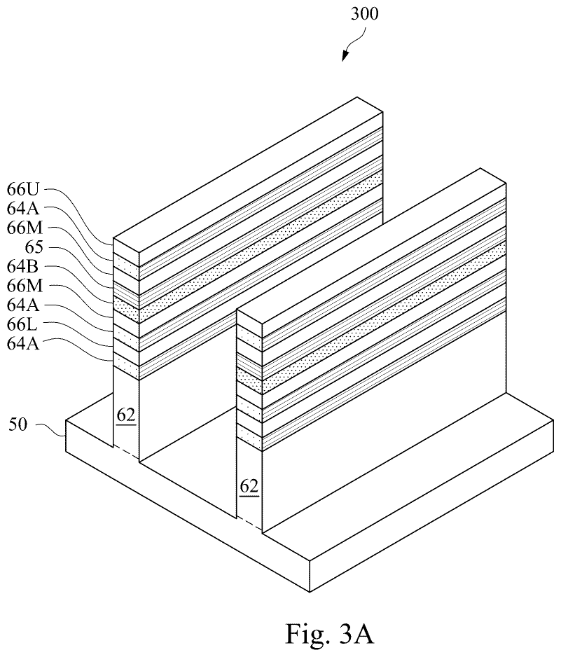

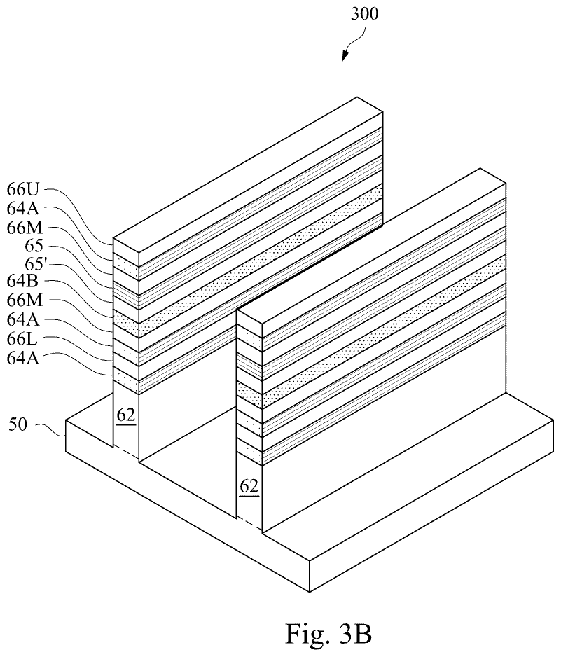

In FIG. 3A, fins 62 are formed in the substrate 50 and nanostructures 64, 65, 66 (including first dummy nanostructures 64A, second dummy nanostructures 64B, lower semiconductor nanostructures 66L, middle semiconductor nanostructures 66M, upper semiconductor nanostructures 66U, and 2D material nanostructures 65) are formed in the multi-layer stack 52. In some embodiments, the nanostructures 64, 65, 66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 65 and 66 by etching the multi-layer stack 52 may define the first dummy nanostructures 64A from the first dummy layers 54A, the second dummy nanostructures 64B from the second dummy layer 54B, the lower semiconductor nanostructure 66L from the bottommost one of the lower semiconductor layers 56L, the upper semiconductor nanostructure 66U from the topmost one of the upper semiconductor layers 56U, the middle semiconductor nanostructures 66M from the topmost one of the lower semiconductor layers 56L and the bottommost one of the upper semiconductor layers 56U, and the 2D material nanostructures 65 from the 2D material layer 55. The first dummy nanostructures 64A and the second dummy nanostructures 64B may further be collectively referred to as the dummy nanostructures 64. The lower semiconductor nanostructures 66L and the upper semiconductor nanostructures 66U may further be collectively referred to as the semiconductor nanostructures 66.

As subsequently described in greater detail, the dummy nanostructures 64 will be removed to form vertically arranged channel regions of CFETs. Specifically, the lower semiconductor nanostructures 66L will act as channel regions for lower nanostructure-FETs of the CFETs. Additionally, the upper semiconductor nanostructures 66U will act as channel regions for upper nanostructure-FETs of the CFETs.

The middle semiconductor nanostructures 66M are the semiconductor nanostructures 66 that are directly below (e.g., in contact with bottom surfaces of) the second dummy nanostructures 64B. Depending on the heights of subsequently formed source/drain regions, the middle semiconductor nanostructures 66M may or may not adjoin any source/drain regions and may or may not act as functional channel regions for the CFETs. The second dummy nanostructures 64B will be subsequently replaced with isolation nanostructures. The isolation nanostructures and the middle semiconductor nanostructures 66M may define boundaries of the lower nanostructure-FETs and the upper nanostructure-FETs.

The 2D material nanostructures 65 are directly above (e.g., in contact with top surfaces of) the second dummy nanostructures 64B. The 2D material nanostructures 65 are graphene nanostructures (e.g., graphene nanosheets), serving as germanium diffusion barriers to prevent germanium atoms diffusing from the second dummy nanostructures 64B (e.g., germanium-rich SiGe nanostructures) into the semiconductor nanostructures 66M and 66U. The 2D material nanostructures 65 can also act as dislocation barriers, inhibiting the propagation of dislocations from the second dummy nanostructures 64B into the overlying nanostructures 66M, 64A and 66U. In some embodiments where the 2D material layer 55 is grown on a catalyst layer 55′ as illustrated in FIG. 2B, the catalyst layer 55′ can be patterned into catalyst nanostructures 65′, such as Cu nanostructures, as illustrated in FIG. 3B.

The fins 62 and the nanostructures 64, 65, and 66 may be patterned by any suitable method. For example, the fins 62 and the nanostructures 64, 65, and 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64, 65, and 66. In some embodiments, a mask (or other layer) may remain on the nanostructures 64, 65, and 66.

Although each of the fins 62 and the nanostructures 64, 65, 66 are illustrated as having a constant width throughout, in other embodiments, the fins 62 and/or the nanostructures 64, 65, 66 may have tapered sidewalls such that a width of each of the fins 62 and/or the nanostructures 64, 65, 66 continuously increases in a direction towards the substrate 50. In such embodiments, each of the nanostructures 64, 65, 66 may have a different width and be trapezoidal in cross-section view.

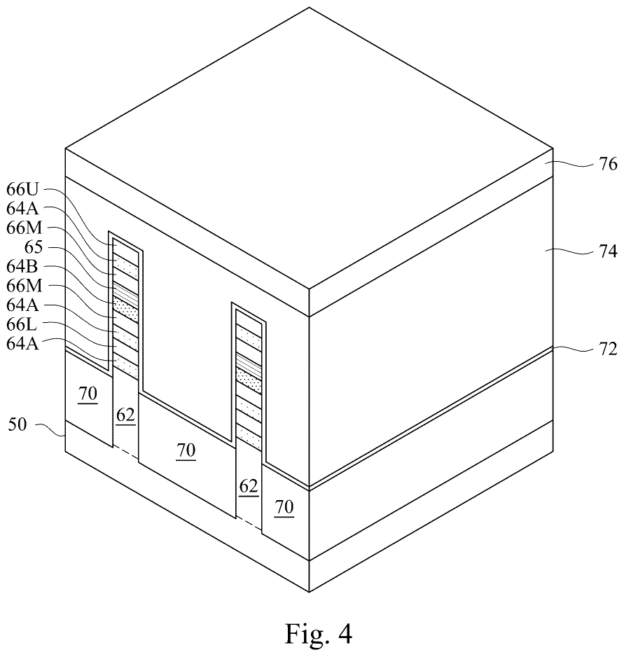

In FIG. 4, isolation regions 70 are formed adjacent to the fins 62. The isolation regions 70 may be formed by depositing an insulating material over the substrate 50, the fins 62, and nanostructures 64, 65, 66, and between adjacent fins 62. The insulating material may be an oxide, such as silicon oxide, a nitride, the like, or a combination thereof, and may be formed by high-density plasma chemical vapor deposition (HDP-CVD), flowable chemical vapor deposition (FCVD), the like, or a combination thereof. Other insulating materials formed by any acceptable process may be used. In some embodiments, the insulating material is silicon oxide formed by an FCVD process. An anneal process may be performed once the insulating material is formed. In an embodiment, the insulating material is formed such that excess insulating material covers the nanostructures 64, 65, 66. Although the insulating material is illustrated as a single layer, some embodiments may utilize multiple layers. For example, in some embodiments a liner (not separately illustrated) may first be formed along a surface of the substrate 50, the fins 62, and the nanostructures 64, 65, 66. Thereafter, a fill material, such as one of the previously described insulating materials may be formed over the liner.

A removal process is then applied to the insulating material to remove excess insulating material over the nanostructures 64, 65, 66. In some embodiments, a planarization process such as a chemical mechanical polish (CMP), an etch-back process, combinations thereof, or the like may be utilized. The planarization process exposes the nanostructures 64, 65, 66 such that top surfaces of the nanostructures 64, 65, 66 and the insulating material are level after the planarization process is complete.

The insulating material is then recessed to form the isolation regions 70. The insulating material is recessed such that upper portions of the fins 62 protrude from between neighboring isolation regions 70. Further, the top surfaces of the isolation regions 70 may have a flat surface as illustrated, a convex surface, a concave surface (such as dishing), or a combination thereof. The top surfaces of the isolation regions 70 may be formed flat, convex, and/or concave by an appropriate etch. The isolation regions 70 may be recessed using an etching process, such as one that is selective to the insulating material (e.g., selectively etches the insulating material at a faster rate than the materials of the fins 62 and the nanostructures 64, 65, 66). For example, an oxide removal using, for example, dilute hydrofluoric (dHF) acid may be used.

In FIG. 4, a dummy dielectric layer 72 is formed on the fins 62 and/or the nanostructures 64, 65, 66. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), poly-crystalline silicon-germanium (poly-SiGe), or the like. The dummy gate layer 74 may be deposited by physical vapor deposition (PVD), CVD, sputter deposition, or other techniques for depositing the selected material. The dummy gate layer 74 may be formed of other materials that have a high etching selectivity to insulating materials. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the fins 62 and/or the nanostructures 64, 65, 66.

Next, in FIG. 5, the mask layer 76 is patterned using acceptable photolithography and etching techniques to form masks 86. The pattern of the masks 86 is then transferred to the dummy gate layer 74 and to the dummy dielectric layer 72 to form dummy gates 84 and dummy dielectrics 82, respectively. The dummy gates 84 and the dummy dielectrics 82 are collectively referred to as dummy gate stacks 85. The dummy gates 84 cover respective channel regions of the nanostructures 64, 65, and 66. The pattern of the masks 86 may be used to physically separate each of the dummy gates 84 from adjacent dummy gates 84. The dummy gates 84 may also have a lengthwise direction (i.e., longitudinal direction) substantially perpendicular to the lengthwise direction of respective fins 62. The masks 86 can optionally be removed after patterning, such as by any acceptable etching technique.

In FIG. 5, gate spacers 90 are formed over the nanostructures 64, 65 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, may be performed to pattern the dielectric material(s). The etching may be anisotropic. The dielectric material(s), when etched, have portions left on the sidewalls of the dummy gates 84 (thus forming the gate spacers 90). Fin spacers may also be formed as part of forming the gate spacers 90.

Source/drain recesses 94 are formed in the nanostructures 64, 65, 66, and the fins 62. Epitaxial source/drain regions will be subsequently formed in the source/drain recesses 94. The source/drain recesses 94 may extend through the nanostructures 64, 65, 66 and into the fins 62. The fins 62 may be etched such that bottom surfaces of the source/drain recesses 94 are disposed above, below, or level with the top surfaces of the isolation regions 70. The source/drain recesses 94 may be formed by etching the nanostructures 64, 65 66, and the substrate 50 using anisotropic etching processes, such as RIE, NBE, or the like. The gate spacers 90 and the dummy gates 84 mask portions of the nanostructures 64, 65 66, and the fins 62 during the etching processes used to form the source/drain recesses 94. A single etch process or multiple etch processes may be used to etch each layer of the nanostructures 64, 65, 66, and the fins 62. Timed etch processes may be used to stop the etching of the source/drain recesses 94 after the source/drain recesses 94 reach a desired depth.

Next, in FIG. 6, inner spacers 98 and dielectric isolation layers 100 are formed. Forming inner spacers 98 and dielectric isolation layers 100 (also referred to as dielectric isolation nanostructures 100) may include an etching process that laterally etches the dummy nanostructures 64A and removes the dummy nanostructure 64B. The etching process may be isotropic and may be selective to the material of the dummy nanostructures 64, so that the dummy nanostructures 64 are etched at a faster rate than the semiconductor nanostructures 66 and the 2D material nanostructures 65. The etching process may also be selective to the material of the dummy nanostructures 64B, so that the dummy nanostructures 64B are etched at a faster rate than the dummy nanostructures 64A. In this manner, the dummy nanostructures 64B may be completely removed from between the middle semiconductor nanostructures 66M and the 2D material nanostructures 65 without completely removing the dummy nanostructures 64A. In some embodiments where the dummy nanostructures 64B are formed of germanium or silicon germanium with a higher germanium atomic percentage than the dummy nanostructures 64A, the dummy nanostructures 64A are formed of silicon germanium with a lower germanium atomic percentage than the dummy structures 64B, the semiconductor nanostructures 66 are formed of silicon free from germanium, and the 2D material nanostructures 65 are formed of graphene free from germanium, the etch process may comprise a dry etch process using chlorine-containing gas, with or without a plasma. Because the dummy gate stacks 85 wrap around sidewalls of the 2D material nanostructures 65 and the semiconductor nanostructures 66 (see FIG. 4), the dummy gate stacks 85 may support the 2D material nanostructures 65 and the upper semiconductor nanostructures 66U, so that the 2D material nanostructures 65 and the upper semiconductor nanostructures 66U do not collapse upon removal of the dummy nanostructures 64B. Further, although sidewalls of the dummy nanostructures 64A are illustrated as being straight after the etching, the sidewalls may be concave or convex.

Inner spacers 98 are formed on sidewalls of the recessed dummy nanostructures 64A, and dielectric isolation layers 100 are formed between the middle semiconductor nanostructures 66M and the 2D material nanostructures 65. As subsequently described in greater detail, source/drain regions will be subsequently formed in the source/drain recesses 94, and the dummy nanostructures 64A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as the etch processes used to form gate structures. Dielectric isolation layers 100, on the other hand, are used to isolate the upper semiconductor nanostructures 66U (collectively) from the lower semiconductor nanostructures 66L (collectively). Further, the dielectric isolation layers 100 may define the boundaries of the lower nanostructure-FETs and the upper nanostructure-FETs.

The inner spacers 98 and the dielectric isolation layers 100 may be formed by conformally depositing an insulating material in the source/drain recesses 94, on sidewalls of the dummy nanostructures 64A, and between the middle semiconductor nanostructures 66M and the 2D material nanostructures 65, and then etching the insulating material. The insulating material may be a non-low-k dielectric material, which may be a carbon-containing dielectric material such as silicon oxycarbonitride, silicon oxycarbide, or the like. The insulating material may be formed by a deposition process, such as ALD, CVD, or the like. The etching of the insulating material may be anisotropic or isotropic. The insulating material, when etched, has portions remaining in the sidewalls of the dummy nanostructures 64A (thus forming the inner spacers 98) and has portions remaining in between the middle semiconductor nanostructures 66M and the 2D material nanostructures 65 (thus forming the dielectric isolation layers 100).

As also illustrated by FIG. 6, lower epitaxial source/drain regions 108L and upper epitaxial source/drain regions 108U are formed. The lower epitaxial source/drain regions 108L are formed in the lower portions of the source/drain recesses 94. The lower epitaxial source/drain regions 108L are in contact with the lower semiconductor nanostructures 66L and are not in contact with the upper semiconductor nanostructures 66U. Inner spacers 98 electrically insulate the lower epitaxial source/drain regions 108L from the dummy nanostructures 64A, which will be replaced with replacement gates in subsequent processes.

The lower epitaxial source/drain regions 108L are epitaxially grown, and have a conductivity type that is suitable for the device type (p-type or n-type) of the lower nanostructure-FETs. When lower epitaxial source/drain regions 108L are n-type source/drain regions, the respective material may include silicon or carbon-doped silicon, which is doped with an n-type dopant such as phosphorous, arsenic, or the like. When lower epitaxial source/drain regions 108L are p-type source/drain regions, the respective material may include silicon or silicon germanium, which is doped with a p-type dopant such as boron, indium, or the like. The lower epitaxial source/drain regions 108L may be in-situ doped, and may be, or may not be, implanted with the corresponding p-type or n-type dopants. During the epitaxy of the lower epitaxial source/drain regions 108L, the upper semiconductor nanostructures 66U may be masked to prevent undesired epitaxial growth on the upper semiconductor nanostructures 66U. After the lower epitaxial source/drain regions 108L are grown, the masks on the upper semiconductor nanostructures 66U may then be removed.

As a result of the epitaxy processes used for forming the lower epitaxial source/drain regions 108L, upper surfaces of the lower epitaxial source/drain regions 108L have facets which expand laterally outward beyond sidewalls of the nanostructures 64, 65 and 66. In some embodiments, adjacent lower epitaxial source/drain regions 108L remain separated after the epitaxy process is completed. In other embodiments, these facets cause neighboring lower epitaxial source/drain regions 108L of a same FET to merge.

A first contact etch stop layer (CESL) 112 and a first interlayer dielectric (ILD) 114 are formed over the lower epitaxial source/drain regions 108L. The first CESL 112 may be formed of a dielectric material having a high etching selectivity from the etching of the first ILD 114, such as silicon nitride, silicon oxide, silicon oxynitride, or the like, which may be formed by any suitable deposition process, such as CVD, ALD, or the like. The first ILD 114 may be formed of a dielectric material, which may be deposited by any suitable method, such as CVD, plasma-enhanced CVD (PECVD), or FCVD. The applicable dielectric material of the first ILD 114 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 114, followed by a planarization process and then an etch-back process. In some embodiments, the first ILD 114 is etched first, leaving the first CESL 112 unetched. An anisotropic etching process is then performed to remove the portions of the first CESL 112 higher than the recessed first ILD 114. After the recessing, the sidewalls of the upper semiconductor nanostructures 66U are exposed.

Upper epitaxial source/drain regions 108U are then formed in the upper portions of the source/drain recesses 94. The upper epitaxial source/drain regions 108U may be epitaxially grown from exposed end surfaces of the upper semiconductor nanostructures 66U. The materials of upper epitaxial source/drain regions 108U may be selected from the same candidate group of materials for forming lower source/drain regions 108L, depending on the desired conductivity type of upper epitaxial source/drain regions 108U. The conductivity type of the upper epitaxial source/drain regions 108U may be opposite the conductivity type of the lower epitaxial source/drain regions 108L. For example, the upper epitaxial source/drain regions 108U may be oppositely doped from the lower epitaxial source/drain regions 108L. The upper epitaxial source/drain regions 108U may be in-situ doped, and/or may be implanted, with an n-type or p-type dopant. Adjacent upper source/drain regions 108U may remain separated after the epitaxy process or may be merged.

After the epitaxial source/drain regions 108U are formed, a second CESL 122 and a second ILD 124 are formed. The materials and the formation methods may be similar to the materials and the formation methods of first CESL 112 and first ILD 114, respectively, and are not discussed in detail herein. The formation process may include depositing the layers for the second CESL 122 and the second ILD 124, and performing a planarization process to remove the excess portion of the corresponding layers. After the planarization process, top surfaces of the second ILD 124, the second CESL 122, the gate spacers 90, and the masks 86 are coplanar (within process variations). The planarization process may leave masks 86 unremoved (as shown), or may remove the masks 86, in which case the top surface of the second ILD 124 is level with the top surface of the dummy gate stacks 85.

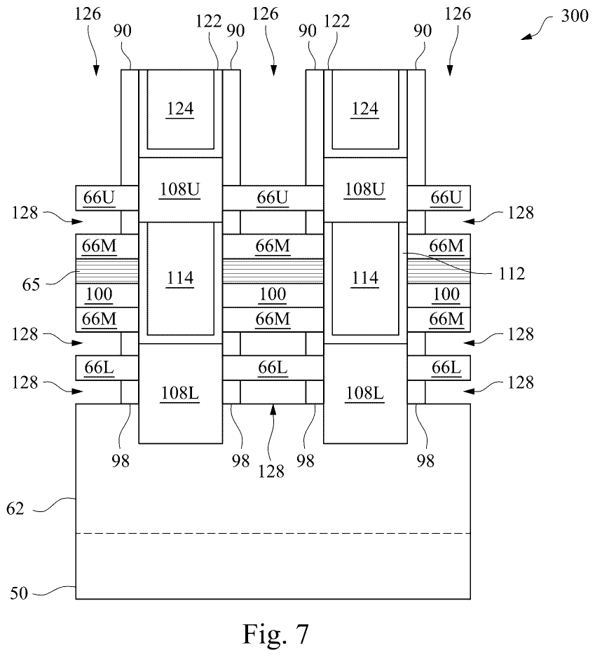

Next, in FIG. 7, the mask 86 (if not removed already) is removed, e.g., by a CMP process. Next, the dummy gate stacks 85 are removed in one or more etching steps, so that gate trenches 126 are formed between the gate spacers 90. In some embodiments, the dummy gates 84 and the dummy dielectrics 82 are removed by an anisotropic dry etch process. For example, the etching process may include a dry etch process using reaction gas(es) that selectively etch the material of the dummy gates 84. Each of the gate trenches 126 exposes and/or overlies portions of nanostructures 66 which act as the channel regions in the resulting devices. The portions of the nanostructures 66 which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the first dummy nanostructures 64A are then removed to form openings 128 in regions between the semiconductor nanostructures 66. In some embodiments where the semiconductor nanostructures 66 are nanosheets, the openings 128 can be referred to as sheet-to-sheet spaces. The remaining portions of the first dummy nanostructures 64A can be removed by any acceptable etch process that selectively etches the material of the first dummy nanostructures 64A at a faster rate than the materials of the 2D material nanostructures 65, the semiconductor nanostructures 66, the inner spacers 98, and the isolation nanostructures 100. The etching may be isotropic. For example, when the first dummy nanostructures 64A are formed of silicon-germanium, the 2D material nanostructures 65 are formed of graphene, the semiconductor nanostructures 66 are formed of silicon, the inner spacers 98 are formed of silicon oxycarbonitride, and the isolation nanostructures 100 are formed of silicon oxycarbonitride, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the semiconductor nanostructures 66 and expand the openings 128.

In FIGS. 8A and 8B, gate dielectrics 132 are formed (e.g., conformally) over the nanostructures 66. In some embodiments, interfacial layers 162 are formed at exposed surfaces of the nanostructures 66 and the fins 62. In some embodiments, the interfacial layer 162 is formed of an oxide of a group II-VI material or an oxide of a group IV material. In the illustrated embodiment, the interfacial layer 162 is an oxide of the material of the nanostructures 66, and is formed by an oxidization process (e.g., a thermal oxidization process and/or a wet oxidization process). In other words, the interfacial layer 162 is formed by converting (e.g., oxidizing) exterior portions of the nanostructures 66 and the fins 62 into an oxide of the material of the nanostructures 66 and the fins. Because the 2D material nanostructures 65 and the isolation nanostructures 100 are not oxidized in the oxidization process, the interfacial layer 162 is not formed on, e.g., the 2D material nanostructures 65, the isolation nanostructures 100 and the isolation regions 70, in the illustrated embodiment. In other embodiments, the interfacial layer 162 is formed by a deposition process (e.g., CVD), in which case the interfacial layer 162 is also formed on, e.g., the 2D material nanostructures 65, the isolation nanostructures 100 and the isolation regions 70. In some embodiments, the interfacial layer 162 is omitted. These and other variations are fully intended to be included within the scope of the present disclosure.

Next, gate dielectric layers 132 are formed (e.g., conformally) over the interfacial layer 162 and along sidewalls of the 2D material nanostructures 65, the isolation nanostructures 100, such that the gate dielectric layer 132 conformally lines the gate trenches 126 and the openings 128. Specifically, the gate dielectric layers 132 are formed on the top surfaces of the fins 62; on the top surfaces, the sidewalls, and the bottom surfaces of the semiconductor nanostructures 66; along sidewalls of the 2D material nanostructures 65, along sidewalls of the isolation nanostructures 100; and along the sidewalls of the gate spacers 90. A gate dielectric layer 132 wraps around all (e.g., four) sides of a corresponding semiconductor nanostructure 66. The gate dielectric layers 132 may also be formed on the sidewalls of the fins 62 (e.g., in embodiments where the top surfaces of the isolation regions 70 are below the top surfaces of the fins 62). In FIG. 8B, the top surfaces of the isolation nanostructures 100 are entirely covered by and in contact with bottom surfaces of the 2D material nanostructures 65. Top surfaces of the 2D material nanostructures 65 are coved by and in contact with bottom surfaces of the middle semiconductor nanostructures 66M and the bottom ends of the interfacial layers 162.

The gate dielectric layers 132 may include an oxide such as silicon oxide or a metal oxide, a silicate such as a metal silicate, combinations thereof, multi-layers thereof, or the like. The gate dielectric layers 132 may be high-k dielectric layers including a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectric layers 132 may include molecular-beam deposition (MBD), ALD, PECVD, and the like.

In some embodiments, a first subset of the gate dielectric layers 132 surrounding the lower semiconductor nanostructures 66L has a different composition than a second subset of the gate dielectric layers 132 surrounding the upper semiconductor nanostructures 66U. This difference in composition allows both the lower nanostructure-FET and the upper nanostructure-FET to share a common gate metal composition, i.e., the same work function material and same fill metal material. For example, when the common gate metal composition includes a p-type work function layer, the gate dielectric layers 132 of an NFET can be doped with an n-type dipole dopant, such as La, Sr, Y, Er, Sc, Mg, or the like, or combinations thereof, while the gate dielectric layers 132 of a PFET can be free of the n-type dipole dopant. Similarly, when the common gate metal composition includes an n-type work function layer, the gate dielectric layers 132 of a PFET can be doped with a p-type dipole dopant, such as Al, Zn, Ga, or the like, or combinations thereof, while the gate dielectric layers 132 of an NFET can be free of the p-type dipole dopant.

In some embodiments, incorporating a dopant into the first subset of the gate dielectric layers 132 may include forming a patterned mask on the second subset of the gate dielectric layers 132, forming a dopant source layer on the first subset of the gate dielectric layers 132 but not on the second subset of the gate dielectric layers, followed by an anneal process performed to thermally diffuse the n-type dopant or p-type dopant from the dopant source layer into the first subset of the gate dielectric layers 132. Once the doping step is completed, the dopant source layer can be removed from the first subset of the gate dielectric layers 132, and the patterned mask can be removed from the second subset of the gate dielectric layers 132.

FIGS. 8A and 8B further illustrate the formation of gate electrodes 134 in the gate trenches 126. The resulting lower nanostructure-FET and the upper nanostructure-FET share a common gate electrode 134. The upper portion of the gate electrode 134 that is higher than isolation nanostructures 100 is referred to as upper gate electrode 134U. The lower portion of the gate electrode 134 that is lower than isolation nanostructures 100 is referred to as lower gate electrode 134L. In some embodiments, the gate electrodes 134 each may include one or more work function layers 135 surrounding the gate dielectric layers 132, and a fill metal 136 surrounding the one or more work function layers 135. In some embodiments, the work function layers 135 and the interfacial layer 162 illustrated in FIG. 8B are not illustrated in FIG. 8A for the sake of clarity.

In some embodiments, the gate electrodes 134 can be formed by, for example, depositing the work function layers 135 surrounding the gate dielectric layers 132, depositing the fill metal 136 to overfill the gate trenches 126, followed by performing a CMP step on the fill metal 136 to remove excess materials of the work function layers 135 and the fill metal 136 outside the gate trenches 126 until the gate spacers 90 and the second ILD 124 are exposed.

In some embodiments, the work function layers 135 encircling each of the gate dielectric layers 132 may be physically separate from the work function layers 135 encircling other ones of the gate dielectric layers 132. In this case, the fill metal 136 (such as ruthenium, tungsten, cobalt, or the like) may fill the spaces between the work function layers 135 on neighboring ones of the gate dielectric layers 132. Alternatively, the work function layers 135 encircling each of the gate dielectric layers 132 may be physically joined to the work function layers 135 encircling other ones of the gate dielectric layers 132.

In some embodiments, the work function layer 135 has a p-type work function, which is higher than about 4.6 eV, and may be in the range between about 4.6 eV and about 5.2 eV. The p-type work function metal in the work function layer 135 for providing p-type work function may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some other embodiments, the work function layer 135 has an n-type work function lower than about 4.5 eV, and may be in the range between about 4.0 eV and about 4.5 eV. The n-type work function metal in the work function layer 135 for providing n-type work function may exemplarily include, but are not limited to, titanium aluminide (TiAl), titanium aluminium nitride (TiAlN), aluminum (Al), aluminum nitride (AlN), and/or other suitable materials. In some embodiments, the fill metal 136 may comprise tungsten, ruthenium, cobalt, combinations thereof, multi-layers thereof, or the like. In some embodiments where the 2D material layer 55 is grown on a catalyst layer 55′ as illustrated in FIG. 2B, the catalyst layer 55′ can be patterned into catalyst nanostructures 65′, such as Cu nanostructures, and the catalyst nanostructures 65′ may remain between the isolation nanostructures 100 and the 2D material nanostructures 65 in the CFET devices, as illustrated in FIG. 8C.

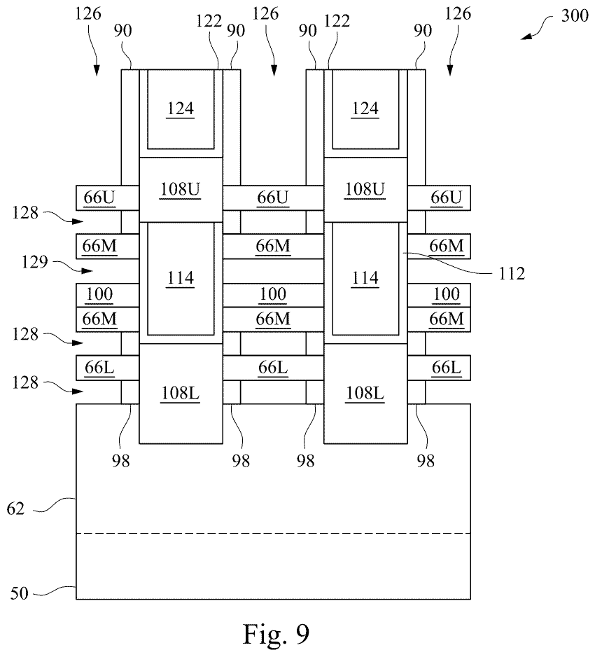

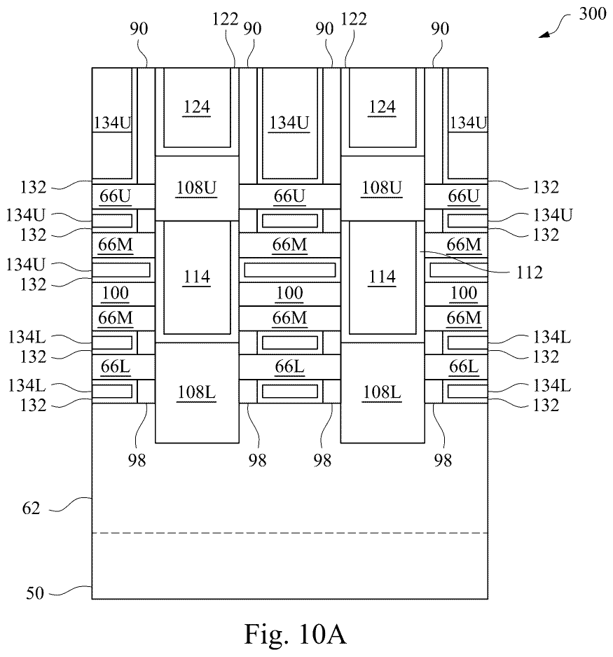

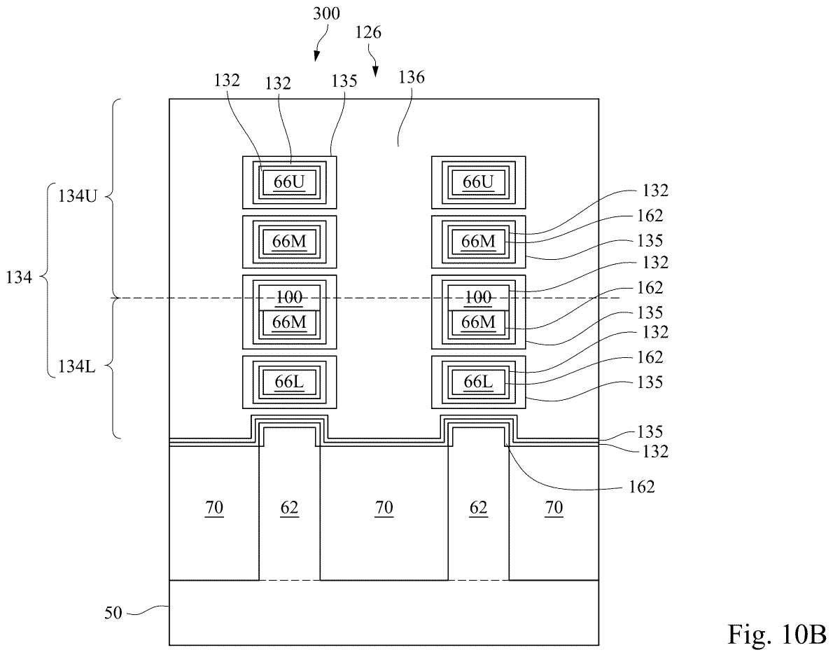

FIGS. 9-10B are cross-sectional views of a CFET device at various stages of manufacturing, in accordance with some other embodiments of the present disclosure. FIGS. 9-10A illustrate cross-sectional views along a similar cross-section as reference cross-section A-A′ in FIG. 1. FIG. 10B illustrates cross-sectional views along a similar cross-section as reference cross-section B-B′ in FIG. 1. The intermediate stage illustrated in FIG. 9 may be subsequent to the intermediate stage as illustrated in FIG. 7, wherein the 2D material nanostructures 65 are removed to form openings 129 in regions between the middle semiconductor nanostructures 66M and the isolation nanostructures 100. In some embodiments, the 2D material nanostructures 65 are removed by using a selectively etching process that etches the 2D material (e.g., graphene) of the 2D material nanostructures 65 at a faster etch rate than etching the semiconductor nanostructures 66. In this way, the 2D material nanostructures 65 can be removed to form openings 129, while leaving the semiconductor nanostructures 66 substantially intact.

In FIGS. 10A and 10B, gate dielectric layers 132 are formed (e.g., conformally) over the nanostructures 66. In some embodiments, interfacial layers 162 are formed at exposed surfaces of the nanostructures 66 and the fins 62. In FIG. 10B, the top surfaces of the isolation nanostructures 100 are in contact with the gate dielectric layers 132, because the 2D material nanostructures 65 have been removed from the top surfaces of the isolation nanostructures 100 in previous step as illustrated in FIG. 9. Other details regarding the gate dielectrics 132 and the interfacial layers 162 are discussed previously with respect to FIGS. 8A and 8B, and thus are not repeated for the sake of brevity. Next, gate electrodes 134 are formed in the gate trenches 126. Details regarding the gate 134 are discussed previously with respect to FIGS. 8A and 8B, and thus are not repeated for the sake of brevity.

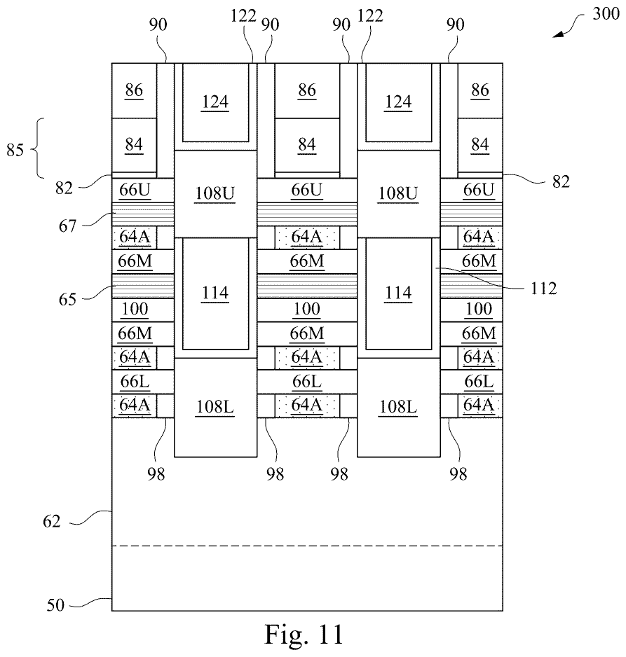

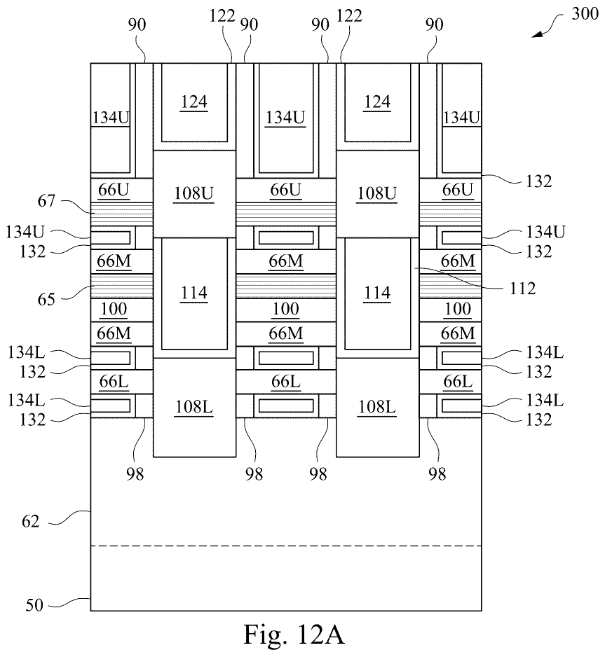

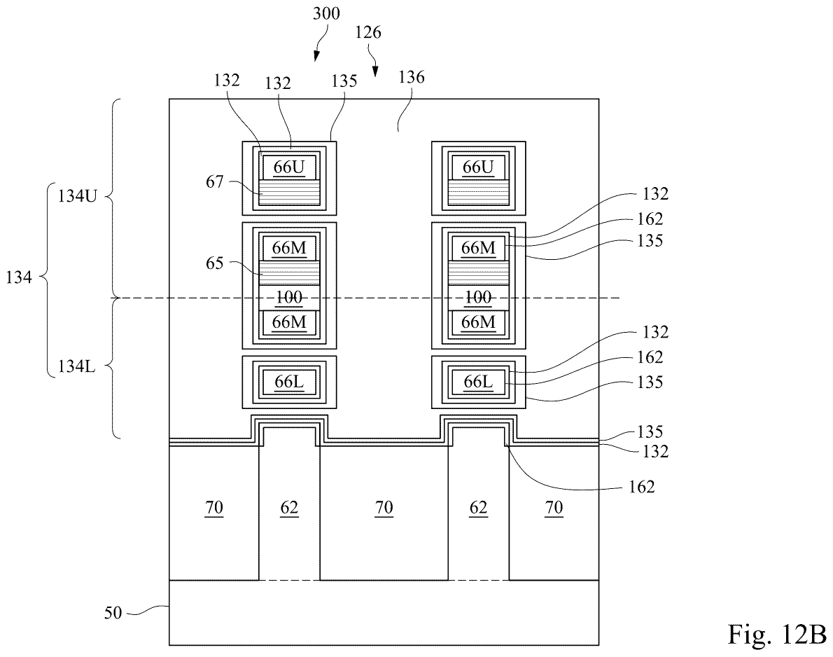

FIGS. 11-12B are cross-sectional views of a CFET device at various stages of manufacturing, in accordance with some other embodiments of the present disclosure. FIGS. 11-12A illustrate cross-sectional views along a similar cross-section as reference cross-section A-A′ in FIG. 1. FIG. 12B illustrates cross-sectional views along a similar cross-section as reference cross-section B-B′ in FIG. 1. The structure illustrated in FIG. 11 is similar to that illustrated in FIG. 6, except that additional 2D material nanostructures 67 are formed between the upper semiconductor nanostructures 66U and the first dummy nanostructures 64A. In some embodiments, the 2D material nanostructures 67 are formed by using similar methods to the formation of 2D material nanostructures 65, as discussed previously with respect to FIGS. 2A-2B and 3A-3B. For example, the 2D material nanostructures 67 are formed by forming a graphene layer on a first dummy layer 54A (e.g., SiGe layer), followed by patterning the graphene layer into the 2D material nanostructures 67.

The 2D material nanostructures 67 are directly above (e.g., in contact with top surfaces of) the first dummy nanostructures 64A. In some embodiments, the 2D material nanostructures 67 are graphene nanostructures (e.g., graphene nanosheets), serving as germanium diffusion barriers to prevent germanium atoms diffusing from the first dummy nanostructures 64A (e.g., SiGe nanostructures) into the upper semiconductor nanostructures 66U. The 2D material nanostructures 67 can also act as dislocation barriers, inhibiting the propagation of dislocations from the first dummy nanostructures 64A into the upper semiconductor nanostructures 66U.

In some embodiments, the 2D material nanostructures 67 each is a monolayer of graphene or a plurality of monolayers of graphene. The total count of monolayer(s) of graphene depends on a desired thickness of the 2D material nanostructures 67. In some embodiments, the 2D material nanostructures 67 each have a thickness in a range in a range from about 1 Å to 50 Å. In some embodiments, the 2D material nanostructures 67 each have a thickness less than a thickness of one of the dummy layers 54 and/or a thickness of the one of the semiconductor layers 56. In some embodiments, the 2D material nanostructures 67 each have a thickness different from the 2D material nanostructures 65, because the 2D material nanostructures 67 are formed at a subsequent stage after forming the 2D material nanostructures 65. For example, a total count of monolayer(s) of graphene in each 2D material nanostructure 67 can be different from a total count of monolayer(s) of graphene in each 2D material nanostructure 65. In some embodiments, a total count of monolayer(s) of graphene in each 2D material nanostructure 67 is greater than a total count of monolayer(s) of graphene in each 2D material nanostructure 65. In some other embodiments, a total count of monolayer(s) of graphene in each 2D material nanostructure 67 is less than a total count of monolayer(s) of graphene in each 2D material nanostructure 65.

In FIGS. 12A and 12B, gate dielectric layers 132 are formed (e.g., conformally) over the nanostructures 66. In some embodiments, interfacial layers 162 are formed at exposed surfaces of the nanostructures 66 and the fins 62. In FIG. 12B, the bottom surfaces of the 2D nanostructures 67 are in contact with the gate dielectric layers 132, and the top surfaces of the 2D nanostructures 67 are covered by and in contact with the bottom surfaces of the upper semiconductor nanostructures 66U and the bottom ends of the interfacial layers 162. Other details regarding the gate dielectrics 132 and the interfacial layers 162 are discussed previously with respect to FIGS. 8A and 8B, and thus are not repeated for the sake of brevity. Next, gate electrodes 134 are formed in the gate trenches 126. Details regarding the gate 134 are discussed previously with respect to FIGS. 8A and 8B, and thus are not repeated for the sake of brevity.

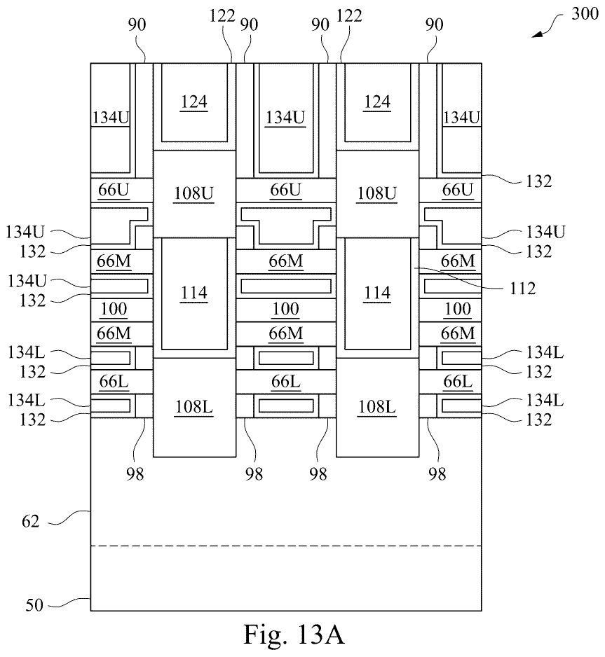

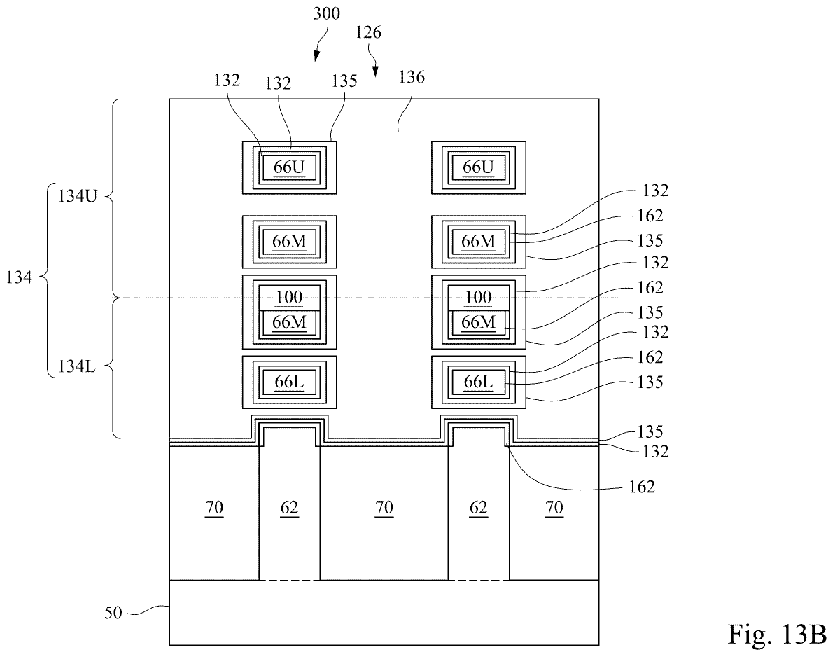

FIGS. 13A-13B are cross-sectional views of a CFET device in accordance with some other embodiments of the present disclosure. FIG. 13A illustrates a cross-sectional views along a similar cross-section as reference cross-section A-A′ in FIG. 1. FIG. 13B illustrates a cross-sectional view along a similar cross-section as reference cross-section B-B′ in FIG. 1. The structure illustrated in FIGS. 13A and 13B is similar to that illustrated in FIGS. 12A and 12B, except that the 2D material nanostructures 65 and 67 are removed and replaced with the gate dielectric layers 132 and gate electrodes 134. For example, the 2D material nanostructures 65 are removed to form openings in regions between the middle semiconductor nanostructures 66M and the isolation nanostructures 100, and the 2D material nanostructures 67 are removed to form openings in regions between the middle semiconductor nanostructures 66M and the upper semiconductor nanostructures 66U. Next, these openings will be filled with the gate dielectric layers 132 and the upper gate electrodes 134U.

In FIG. 13B, the top surfaces of the isolation nanostructures 100 are in contact with the gate dielectric layers 132, because the 2D material nanostructures 65 have been removed from the top surfaces of the isolation nanostructures 100. Similarly, the bottom surfaces of the upper semiconductor nanostructures 66U are in contact with the interfacial layers 162, because the 2D material nanostructures 67 have been removed from the bottom surfaces of the upper semiconductor nanostructures 66U. Other details regarding the gate dielectrics 132, the interfacial layers 162, and the gate electrodes 134U, 134L are discussed previously with respect to FIGS. 8A and 8B, and thus are not repeated for the sake of brevity.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the 2D material nanostructures can serve as germanium diffusion barriers to impede the migration of Ge atoms from the SiGe nanostructures into the silicon nanostructures. Another advantage is that the 2D material nanostructures can further serve as dislocation barriers to prevent dislocations within the SiGe layer from propagating to the silicon layer grown above it.

In some embodiments, a method includes forming a first semiconductor nanostructure (e.g., nanostructure 66L) over a substrate; forming a first 2D material nanostructure (e.g., nanostructure 65) over the first semiconductor nanostructure; forming a second semiconductor nanostructure (e.g., nanostructure 66U) over the first 2D material nanostructure; forming a dielectric isolation nanostructure (e.g., nanostructure 100) between the first semiconductor nanostructure and the second semiconductor nanostructure; and forming a gate electrode (e.g., electrode 134) surrounding the first semiconductor nanostructure and the second semiconductor nanostructure. In some embodiments, the dielectric isolation nanostructure is in contact with the first 2D material nanostructure. In some embodiments, the dielectric isolation nanostructure is below the first 2D material nanostructure. In some embodiments, the first 2D material nanostructure is graphene. In some embodiments, forming the dielectric isolation nanostructure comprises replacing a germanium-containing nanostructure (e.g., nanostructure 64B) with a dielectric material. In some embodiments, the germanium-containing nanostructure (e.g., nanostructure 64B) has a greater germanium atomic percentage than the first semiconductor nanostructure (e.g., nanostructure 66L). In some embodiments, the germanium-containing nanostructure (e.g., nanostructure 64B) has a greater germanium atomic percentage than the second semiconductor nanostructure (e.g., nanostructure 66U). In some embodiments, the method further includes removing the first 2D material nanostructure prior to forming the gate electrode. In some embodiments, the method further includes forming a second 2D material nanostructure (e.g., nanostructure 67) above the first 2D material nanostructure and below the second semiconductor nanostructure. In some embodiments, the second 2D material nanostructure and the first 2D material nanostructure are formed of a same material. In some embodiments, the second 2D material nanostructure and the first 2D material nanostructure are graphene.

In some embodiments, a method includes forming a first semiconductor channel region (e.g., 66L) above a substrate; forming a germanium-containing layer (e.g., 64B) above the first semiconductor channel region; forming a first graphene layer (e.g., 65) above the germanium-containing layer; forming a second semiconductor channel region (e.g., 66U) above the first graphene layer; replacing the germanium-containing layer with a dielectric layer (e.g., 100); and forming a gate electrode (e.g., 134) over the first semiconductor channel region and the second semiconductor channel region. In some embodiments, the first graphene layer is formed on a top surface of the germanium-containing layer. In some embodiments, after replacing the germanium-containing layer with the dielectric layer, the dielectric layer has a top surface in contact with the first graphene layer. In some embodiments, the method further includes forming a second graphene layer (e.g., 67) above the first graphene layer and spaced apart from the first graphene layer. In some embodiments, the second semiconductor channel region is formed on a top surface of the second graphene layer.

In some embodiments, a device includes a first semiconductor nanostructure, a second semiconductor nanostructure above the first semiconductor nanostructure, a dielectric isolation nanostructure vertically between the first semiconductor nanostructure and the second semiconductor nanostructure, a first 2D material nanostructure vertically between the dielectric isolation nanostructure and the second semiconductor nanostructure, and a gate electrode surrounding the first semiconductor nanostructure and the second semiconductor nanostructure. In some embodiments, the first 2D material nanostructure is in contact with a top surface of the dielectric isolation nanostructure. In some embodiments, the first 2D material nanostructure is graphene. In some embodiments, the device further includes a second 2D material nanostructure vertically between the first 2D material nanostructure and the second semiconductor nanostructure. The second 2D material nanostructure is spaced apart from the first 2D material nanostructure at least by the gate electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first semiconductor nanostructure over a substrate;
forming a first 2D material nanostructure over the first semiconductor nanostructure;
forming a second semiconductor nanostructure over the first 2D material nanostructure;
forming a dielectric isolation nanostructure between the first semiconductor nanostructure and the second semiconductor nanostructure; and
forming a gate electrode surrounding the first semiconductor nanostructure and the second semiconductor nanostructure.

2. The method of claim 1, wherein the dielectric isolation nanostructure is in contact with the first 2D material nanostructure.

3. The method of claim 1, wherein the dielectric isolation nanostructure is below the first 2D material nanostructure.

4. The method of claim 1, wherein the first 2D material nanostructure is graphene.

5. The method of claim 1, wherein forming the dielectric isolation nanostructure comprises:
replacing a germanium-containing nanostructure with a dielectric material.

6. The method of claim 5, wherein the germanium-containing nanostructure has a greater germanium atomic percentage than the first semiconductor nanostructure.

7. The method of claim 5, wherein the germanium-containing nanostructure has a greater germanium atomic percentage than the second semiconductor nanostructure.

8. The method of claim 1, further comprising:
removing the first 2D material nanostructure prior to forming the gate electrode.

9. The method of claim 1, further comprising:
forming a second 2D material nanostructure above the first 2D material nanostructure and below the second semiconductor nanostructure.

10. The method of claim 9, wherein the second 2D material nanostructure and the first 2D material nanostructure are formed of a same material.

11. The method of claim 9, wherein the second 2D material nanostructure and the first 2D material nanostructure are graphene.

12. A method, comprising:
forming a first semiconductor channel region above a substrate,
forming a germanium-containing layer above the first semiconductor channel region;
forming a first graphene layer above the germanium-containing layer;
forming a second semiconductor channel region above the first graphene layer;
replacing the germanium-containing layer with a dielectric layer; and
forming a gate electrode over the first semiconductor channel region and the second semiconductor channel region.

13. The method of claim 12, wherein the first graphene layer is formed on a top surface of the germanium-containing layer.

14. The method of claim 12, wherein after replacing the germanium-containing layer with the dielectric layer, the dielectric layer has a top surface in contact with the first graphene layer.

15. The method of claim 12, further comprising:
forming a second graphene layer above the first graphene layer and spaced apart from the first graphene layer.

16. The method of claim 15, wherein the second semiconductor channel region is formed on a top surface of the second graphene layer.

17. A device, comprising:
a first semiconductor nanostructure;
a second semiconductor nanostructure above the first semiconductor nanostructure;
a dielectric isolation nanostructure vertically between the first semiconductor nanostructure and the second semiconductor nanostructure;
a first 2D material nanostructure vertically between the dielectric isolation nanostructure and the second semiconductor nanostructure; and
a gate electrode surrounding the first semiconductor nanostructure and the second semiconductor nanostructure.

18. The device of claim 17, wherein the first 2D material nanostructure is in contact with a top surface of the dielectric isolation nanostructure.

19. The device of claim 17, wherein the first 2D material nanostructure is graphene.

20. The device of claim 17, further comprising:
a second 2D material nanostructure vertically between the first 2D material nanostructure and the second semiconductor nanostructure, the second 2D material nanostructure being spaced apart from the first 2D material nanostructure at least by the gate electrode.
